(19) United States
(12) Patent Application Publication
(10) Pub. No.: US 2026/0339219 A1
(43) Pub. Date: Oct. 29, 2026

(54) MULTI-BEAM SPECTRAL PROGRAMMER

(71) Applicant: KLA Corporation, Milpitas, CA (US)

(72) Inventors: Andrew V. Hill, Berkley, CA (US); Elad Farchi, Milpitas, CA (US)

(21) Appl. No.: 19/193,328

(22) Filed: Apr. 29, 2025

(51) Int. Cl. G03F 7/00; G01J 3/02; G01J 3/18

(52) U.S. Cl. CPC G03F 7/706849; G01J 3/0229; G01J 3/18; G03F 7/706833

(57) ABSTRACT

An illumination system is disclosed. The illumination system includes one or more illumination sources generate one or more illumination beams. The illumination system includes a spectral control subsystem. The spectral control subsystem includes a beamsplitter configured to split each of the one or more illumination beams into two or more beams. The spectral control subsystem includes one or more dispersive elements configured to spectrally disperse the two or more beams as spectrally-dispersed beams. The spectral control subsystem includes one or more two-dimensional spatial light modulators, wherein each of the spectrally-dispersed beams is directed to a spatially separated region of the one or more two-dimensional spatial light modulators, wherein the two-dimensional spatial light modulator independently controls spectra of the spectrally-dispersed beams, wherein the one or more dispersive elements receive the spectrally-dispersed beams from the one or more two-dimensional spatial light modulators and remove spectral dispersion from the spectrally-dispersed beams.

### TECHNICAL FIELD

The present disclosure relates generally to metrology and, more particularly, to spectral control of illumination beams within a metrology system.

### BACKGROUND

Metrology systems typically characterize metrology measurements (e.g., overlay) of a sample by measuring the different portions or features on a sample. As the size of fabricated features decreases and the feature density increases, the demands on metrology systems needed to characterize these features increase. In particular, smaller features require more sensitive and more accurate measurements of small alignment errors, which may in turn lead to increased energy costs when performing metrology measurements.

Within an illumination system, spatial chromatic dispersion may be introduced into an illumination beam and subsequently removed after the beam interacts with a spatial light modulator (SLM) to enhance the efficiency of the illumination system. Such a method is described in U.S. Pat. No. 9,921,050, which is incorporated herein by reference in its entirety. However, such solutions are configured to map a single illumination input to a single illumination output. Adjusting the spectrum and intensity of single beams may be slow and require an undesirable amount of hardware in order to control the required number of beams for metrology applications. Accordingly, it is desirable to develop systems and methods to address these demands.

### SUMMARY

An illumination system is disclosed, in accordance with one or more embodiments of the present disclosure. In embodiments, the illumination system includes one or more illumination sources, each of the one or more illumination sources configured to generate one or more illumination beams. In embodiments, the illumination system includes a spectral control subsystem. In embodiments, the spectral control subsystem includes a beamsplitter, wherein the beamsplitter is configured to split each of the one or more illumination beams into two or more beams. In embodiments, the spectral control subsystem includes one or more dispersive elements, wherein the one or more dispersive elements are configured to spectrally disperse the two or more beams as spectrally-dispersed beams. In embodiments, the spectral control subsystem includes one or more two-dimensional spatial light modulators, wherein each of the spectrally-dispersed beams is directed to a spatially separated region of the one or more two-dimensional spatial light modulators, wherein the two-dimensional spatial light modulator independently controls spectra of the spectrally-dispersed beams, wherein the one or more dispersive elements receive the spectrally-dispersed beams from the one or more two-dimensional spatial light modulators and remove spectral dispersion from the spectrally-dispersed beams to form two or more output beams.

A metrology system is disclosed, in accordance with one or more embodiments of the present disclosure. In embodiments, the metrology system includes one or more illumination sources, each of the one or more illumination sources configured to generate one or more illumination beams. In embodiments, the metrology system includes a spectral control subsystem. In embodiments, the spectral control subsystem includes a beamsplitter, wherein the beamsplitter is configured to split each of the one or more illumination beams into two or more beams. In embodiments, the spectral control subsystem includes one or more dispersive elements, wherein the one or more dispersive elements are configured to spectrally disperse the two or more beams as spectrally-dispersed beams. In embodiments, the spectral control subsystem includes one or more two-dimensional spatial light modulators, wherein each of the spectrally-dispersed beams is directed to a spatially separated region of the one or more two-dimensional spatial light modulators, wherein the two-dimensional spatial light modulator independently controls spectra of the spectrally-dispersed beams, wherein the one or more dispersive elements receive the spectrally-dispersed beams from the one or more two-dimensional spatial light modulators and remove spectral dispersion from the spectrally-dispersed beams to form two or more output beams. In embodiments, the metrology system includes two or more illumination channels, each of the one or more illumination channels configured to receive one of the two or more output beams. In embodiments, the metrology system includes one or more measurement heads configured to illuminate a portion of a sample using the two or more output beams and capture sample illumination from the sample. In embodiments, the metrology system includes one or more detectors configured to generate detection signals based on the sample illumination from the sample. In embodiments, the metrology system includes a controller including one or more processors configured to execute a set of program instructions stored in memory, the set of program instructions configured to cause the one or more processors to determine at least one metrology measurement of the sample based on the detection signals.

A metrology method is disclosed, in accordance with one or more embodiments of the present disclosure. In embodiments, the metrology method includes generating one or more illumination beams. In embodiments, the metrology method includes splitting one or more illumination beams into two or more beams. In embodiments, the metrology method includes dispersing each of the two or more beams with one or more dispersive elements to form spectrally-dispersed beams. In embodiments, the metrology method includes directing each of the spectrally-dispersed beams to a spatially separate region on one or more two-dimensional spatial light modulators. In embodiments, the metrology method includes controlling spectra of the spectrally-dispersed beams with the one or more two-dimensional spatial light modulators. In embodiments, the metrology method includes removing dispersion from the spectrally-dispersed beams from the one or more two-dimensional spatial light modulators with the one or more dispersive elements to form two or more output beams.

### BRIEF DESCRIPTION OF THE DRAWINGS

The numerous advantages of the disclosure may be better understood by those skilled in the art by reference to the accompanying figures.

FIG. 1A illustrates a schematic view of an illumination system, in accordance with one or more embodiments of the present disclosure.

FIG. 1B illustrates a side view the illumination system showing dispersion of one illumination beam on a spatial light modulator, in accordance with one or more embodiments of the present disclosure.

FIG. 2A illustrates a top view of a schematic of the illumination system including two spatial light modulators, in accordance with one or more embodiments of the present disclosure.

FIG. 2B illustrates a side view of a schematic of the illumination system including two spatial light modulators, in accordance with one or more embodiments of the present disclosure.

FIG. 3A illustrates a top view of a schematic of the illumination system including two dispersive elements, in accordance with one or more embodiments of the present disclosure.

FIG. 3B illustrates a side view of a schematic of the illumination system including two dispersive elements, in accordance with one or more embodiments of the present disclosure.

FIG. 4 illustrates multiple dispersed beams positioned on a two-dimensional spatial light modulator, in accordance with one or more embodiments of the present disclosure.

FIG. 5 illustrates a block diagram of a metrology system, in accordance with one or more embodiments of the present disclosure.

FIG. 6 illustrates a flow diagram of a metrology method, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to an illumination system including a spectral control subsystem designed to control multiple input beams. An input illumination beam may be split into multiple beams, with the number of beams corresponding to the number of intended outputs. Chromatic dispersion may then be introduced to each of the multiple beams. The spectrally-dispersed beams may be positioned on spatially separated regions of a two-dimensional spatial light modulator in order to locally reduce the intensity of resolved spectral regions of each of the multiple beams. The chromatic dispersion may then be removed from the spectrally-dispersed beams after the spectrally dispersed beams have been interacted with (e.g., reflected or transmitted) the two-dimensional spatial light modulator. After the chromatic dispersion is removed to form output beams, each of the output beams may be available for routing to the illumination channel of a measurement head.

Such a technique may provide for high-speed, light-efficient control of both spectrum and intensity of illumination in inspection and/or metrology (e.g., overlay metrology, critical dimension metrology, film thickness control, wafer geometry metrology, in-situ process monitoring, and/or advanced patterning control). Output of light sources used in overlay metrology can span a broad spectral range, however, a limited portion of the broad spectrum is defined for each measurement. Therefore, it may be beneficial to control the spectrum of illumination used. Additionally, both spectral bandwidth and center wavelength need to be defined and, in some cases, it may be desirable to control the spectral shape of the illumination within the pass band.

Additionally, intensity of illumination needs to be controlled to avoid sensor saturation and to minimize photon noise in the measurement and high-speed control of both spectral shape and intensity are required for maximal system throughput. Light efficiency in the illumination system may be provided by the techniques described herein and may improve system throughput and reduces the power required from the light source.

It may also be desirable to provide an illuminator with a single light source that simultaneously supports multiple outputs (e.g., multiple illumination channels and measurement heads) and enables independent, high-speed, light-efficient control of both spectrum and intensity in each output. A single overlay metrology system may contain multiple illumination channels, each of which may require independent control of spectrum and intensity and may contain multiple heads for making simultaneous measurements of multiple targets on one or more wafers. Metrology system size and cost can be minimized by enabling one light source to simultaneously support multiple illumination channels and/or multiple measurement heads by splitting a single illumination beam into multiple beams before spectral control occurs and before the illumination beam passes into the illumination channels and/or measurement heads.

Additionally, the techniques described herein for sharing components of a spectral control subsystem of the metrology system (e.g., sharing a light source, sharing dispersive elements, sharing a spatial light modulator, and/or sharing lenses and mirrors) may also reduce the overall cost of the metrology system. Further, sharing components of a spectral control subsystem of the metrology system can reduce the package size and service costs, as there are a reduced number of components to package and/or service.

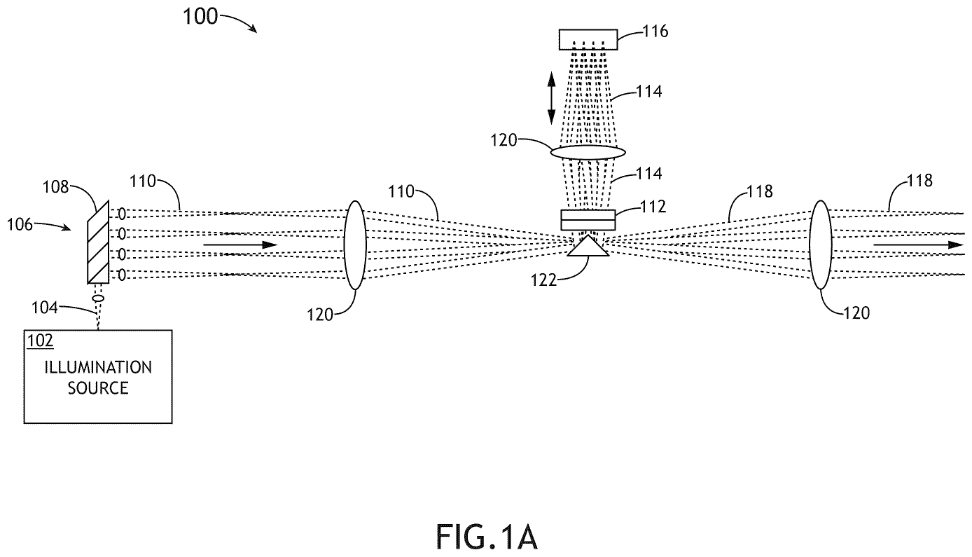

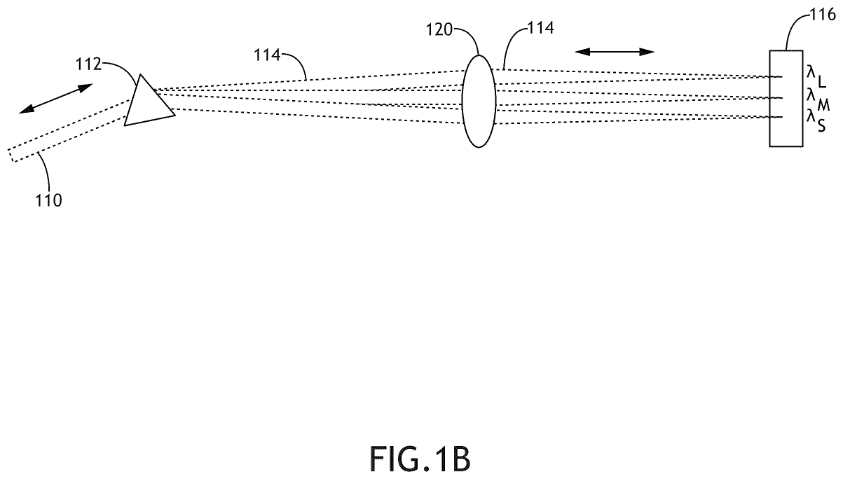

FIG. 1A illustrates a schematic of an illumination system 100, in accordance with one or more embodiments of the present disclosure.

In embodiments, the illumination system 100 includes one or more illumination sources 102. Each illumination source 102 may be configured to generate one or more illumination beams 104. The illumination beams 104 may be configured as coherent illumination beams 104 (e.g., an illumination beam 104 generated by a coherent illumination source 102) or incoherent illumination beams 104 (e.g., an illumination beam 104 generated by an incoherent illumination source 102).

In embodiments, the illumination system 100 includes a coherent illumination source 102. The coherent illumination source 102 may be configured to generate coherent illumination beams 104. The coherent illumination source 102 may be any coherent illumination source 102 known in the art suitable for generating coherent illumination beams 104. For example, the coherent illumination source 102 may be laser source (e.g., a supercontinuum laser source) or a certain light emitting diode (LED) lights. A singular coherent illumination source 102 may generate all of the illumination beams 104 used in the illumination system 100.

In embodiments, the illumination system 100 includes an incoherent illumination source 102. The incoherent illumination source 102 may be configured to generate incoherent illumination beams 104. The incoherent illumination source 102 may be any incoherent illumination source 102 known in the art suitable for generating incoherent illumination beams 104. For example, the incoherent illumination source 102 may be a lamp source (e.g., a laser-sustained plasma light source), a supercontinuum source, a broadband illumination source, or a laser sustained plasma light source. A singular incoherent illumination source 102 may generate all of the illumination beams 104 used in the illumination system 100.

In Embodiments, the illumination system 100 includes a spectral control subsystem 106.

In embodiments, the spectral control subsystem 106 includes a beamsplitter 108. The beamsplitter 108 may receive the illumination beams 104 produced by the illumination source 102. The beamsplitter 108 may directly receive the illumination beams 104 produced by the illumination source 102 or one or more optical elements may modify the illumination beams 104 before they reach the beamsplitter 108.

The beamsplitter 108 may be configured to split each of the illumination beams 104 into two or more beams 110.

In embodiments, the spectral control subsystem 106 includes one or more dispersive elements 112. The dispersive elements 112 may receive the beams 110 generated by the beamsplitter 108. The dispersive elements 112 may directly receive the beams 110 generated by the beamsplitter 108 or one or more optical elements may modify the beams 110 before they reach the dispersive elements 112.

The dispersive elements 112 may be configured to spectrally disperse the beams 110 to form spectrally-dispersed beams 114. The dispersive elements 112 may be any combination of prisms, acousto-optic modulators, and/or diffraction gratings.

In embodiments, the spectral control subsystem 106 includes one or more two-dimensional spatial light modulators (2D SLM) 116. In embodiments, the one or more two-dimensional spatial light modulators 116 may be a single two-dimensional spatial light modulator 116. The two-dimensional spatial light modulators 116 may receive the spectrally-dispersed beams 114 generated by the dispersive elements 112. The two-dimensional spatial light modulators 116 may directly receive the spectrally-dispersed beams 114 generated by the dispersive elements 112 or one or more optical elements may modify the spectrally-dispersed beams 114 before they reach the two-dimensional spatial light modulators 116.

The two-dimensional spatial light modulators 116 may receive each of the spectrally-dispersed beams 114 on a spatially separated region of the two-dimensional spatial light modulators 116 (e.g., the spectrally-dispersed beams 114 do not overlap on the two-dimensional spatial light modulators 116). Therefore, the spectrally-dispersed beams 114 may be able to independently control the spectra of the spectrally-dispersed beams 114 received from the dispersive elements 112.

The two-dimensional spatial light modulators 116 may be any combination of elements which are able to control any characteristic of the spectrally-dispersed beams 114. For example, the two-dimensional spatial light modulators 116 may be configured to control intensity, phase, and/or polarization of the spectrally-dispersed beams 114. By way of another example, the two-dimensional spatial light modulators 116 may be designed to reduce the intensity of the spectrally-dispersed beams 114. The two-dimensional spatial light modulators 116 may also provide spatial control of intensity, phase, and/or polarization of the spectrally-dispersed beams 114. Because the spectrally-dispersed beams 114 are spectrally dispersed the spatial control of intensity, phase, and/or polarization may be mapped to wavelength-specific control.

The two-dimensional spatial light modulators 116 may be any combination of a micro-mirror array, a diffractive mirror array, a silicon light valve, a liquid crystal display (LCD) array, and/or a liquid crystal on silicon (LCOS) array.

The dispersive elements 112 may subsequently remove the spectral dispersion from the spectrally-dispersed beams 114 received from the two-dimensional spatial light modulators 116 in order to form two or more output beams 118. In this way, illumination may be pass through the dispersive elements 112 twice. For example, a first pass through the dispersive elements 112 may result in forming spectrally-dispersed beams 114, while a second pass through the dispersive elements 112 may result in forming output beams 114 (e.g., undispersed output beams 118).

It should be noted that dispersion and removing the dispersion may occur through a single dispersive element 112 or multiple dispersive elements 112. For example, the spectrally-dispersed beams 114 may return to the same dispersive element 112 to remove dispersion. By way of another example, the spectrally-dispersed beams 114 may be dispersed by one dispersive element 112 and have dispersion removed by a different dispersive element 112 (e.g., distinct dispersive elements to disperse and remove dispersion).

The two-dimensional spatial light modulators 116 may be configured to both receive spectrally-dispersed beams 114 from the dispersive elements 112 and return the spectrally-dispersed beams 114 to the dispersive elements 112. Therefore, the two-dimensional spatial light modulators 116 may need to be able to separate incoming and outgoing spectrally-dispersed beams 114. For example, the two-dimensional spatial light modulators 116 may separate the incoming and outgoing spectrally-dispersed beams 114 by tilting the two-dimensional spatial light modulators 116. By way of another example, the two-dimensional spatial light modulators 116 may separate the incoming and outgoing spectrally-dispersed beams 114 based on amplitude splitting by the beamsplitter 108. By way of another example, the two-dimensional spatial light modulators 116 may separate the incoming and outgoing spectrally-dispersed beams 114 based on polarization with the beamsplitter 108 with a quarter wave plate in double pass.

It should be noted that the beamsplitter 108 may be located in various places within the spectral control subsystem 106. For example, the beamsplitter 108 may be located prior to a dispersive element 112 (e.g., therefore before the two-dimensional spatial light modulators 116 as well). By way of another example, the beamsplitter 108 may be located between a dispersive element 112 and the two-dimensional spatial light modulators 116.

In embodiments, the spectral control subsystem 106 may include one or more lenses 120. The lenses 120 may be configured to converge or diverge light (e.g., any of the illumination beams 104, the beams 110, the spectrally-dispersed beams 114 and/or the output beams 118).

In embodiments, the spectral control subsystem 106 may include one or more mirrors 122 (e.g., a pickoff mirror). The mirrors 122 may direct light (e.g., the illumination beams 104) from the illumination source 102 to the dispersive elements 112 and/or the two-dimensional spatial light modulators 116. Additionally, the mirrors 122 may direct output beams 118 away from the dispersive elements 112 and/or the two-dimensional spatial light modulators 116.

FIG. 1B illustrates a side view a portion of the illumination system 100 showing dispersion of a spectrally-dispersed beam 114 on a spatial light modulator 116, in accordance with one or more embodiments of the present disclosure.

The spectrally-dispersed beam 114 may be spatially spread out on the two-dimensional spatial light modulators 116 based on their wavelength. For example, long wavelengths (λ_{L}) may be on one side of the two-dimensional spatial light modulators 116, while short wavelengths (λ_{S}) may be on the other side of the two-dimensional spatial light modulators 116. Additional wavelengths (e.g., medium wavelengths (λ_{M})) may be dispersed between the long wavelengths and the short wavelengths.

Additionally, FIG. 1B illustrates the spectrally-dispersed beam 114 traveling to the two-dimensional spatial light modulators 116 and returning from the two-dimensional spatial light modulators 116 along the same path and exiting through the dispersive element.

FIG. 1B illustrates a single beam 110 entering a dispersive element 112, however, it should be noted that multiple beams 110 may enter the same dispersive element 112 to be dispersed.

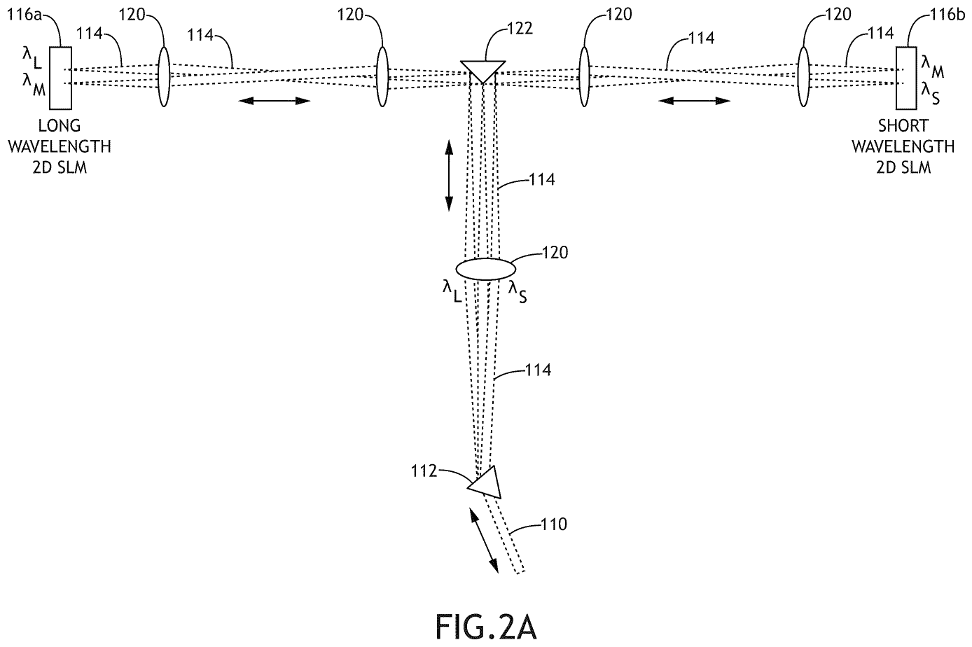

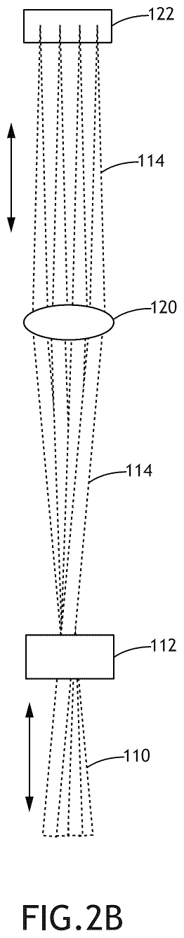

FIG. 2A illustrates a top view of a schematic of an illumination system 100 including two spatial light modulators 116, in accordance with one or more embodiments of the present disclosure. FIG. 2B illustrates a side view of a schematic of an illumination system 100 including two spatial light modulators 116, in accordance with one or more embodiments of the present disclosure. It is noted that the multiple two-dimensional spatial light modulators 116 may be seen in FIG. 2A but not FIG. 2B.

In embodiments, it may be preferable to include multiple two-dimensional spatial light modulators 116 within the spectral control subsystem 106 of the illumination system 100. For example, each of the two-dimensional spatial light modulators 116 may be designated to handle different spectra of the spectrally-dispersed beams 114.

In embodiments, the illumination system 100 includes a first two-dimensional spatial light modulator 116a and a second two-dimensional spatial light modulator 116b to modulate different spectra of the spectrally-dispersed beams 114. For example, the first two-dimensional spatial light modulator 116a may be designed to receive portions of the spectrally-dispersed beams 114 having a wavelength above a selected threshold. In this way, the first two-dimensional spatial light modulator 116a may receive portions of the spectrally-dispersed beams 114 including long wavelengths and medium wavelengths. By way of another example, the second two-dimensional spatial light modulator 116b may be designed to receive portions of the spectrally-dispersed beams 114 having a wavelength below a selected threshold. In this way, the second two-dimensional spatial light modulator 116b may receive portions of the spectrally-dispersed beams 114 including short wavelengths and medium wavelengths.

The selected threshold may be any value between the longest wavelength and the shortest wavelength of the spectrally-dispersed beams 114. For example, the selected threshold may be the average of longest wavelength and the shortest wavelength of the spectrally-dispersed beams 114 (e.g., the selected threshold may be exactly in the middle). However, it may be desirable for some applications for the selected threshold to be closer to the longest wavelength or the shortest wavelength of the spectrally-dispersed beams 114.

In embodiments with two two-dimensional spatial light modulators 116, only one dispersive element 112 may still be used to form the spectrally-dispersed beams 114. For example, the spectrally-dispersed beams 114 may be directed to the two-dimensional spatial light modulators 116 with mirrors 122. In this way, the position of the mirrors 122 may be connected to the selected threshold, as the mirror may split the spectrally-dispersed beams 114 to send longer wavelengths to the first two-dimensional spatial light modulator 116a and shorter wavelengths to the second two-dimensional spatial light modulator 116b.

The first two-dimensional spatial light modulator 116a and the second two-dimensional spatial light modulator 116b may be positioned in any manner relative to each other. For example, the first two-dimensional spatial light modulator 116a and second two-dimensional spatial light modulator 116b may be positioned opposite each other (e.g., as shown in FIG. 2A). By way of another example, the first two-dimensional spatial light modulator 116a and second two-dimensional spatial light modulator 116b may be positioned at a right angle relative to each other.

Additionally, the spectrally-dispersed beams 114 modulated by the first two-dimensional spatial light modulator 116a and the second two-dimensional spatial light modulator 116b may have its dispersion removed by the same dispersive elements 112 or different dispersive elements 112. For example, the same dispersive elements 112 that forms the spectrally-dispersed beams 114 may also remove the dispersion after the spectrally-dispersed beams 114 have been modulated by the first two-dimensional spatial light modulator 116a and second two-dimensional spatial light modulator 116b.

Additionally, it is noted that while spectral control with two two-dimensional spatial light modulators 116 is illustrated in FIGS. 2A and 2B, it should be noted that any number of two-dimensional spatial light modulators 116 may be used, and therefore, the use of two two-dimensional spatial light modulators 116 should be interpreted as illustrative rather than limiting.

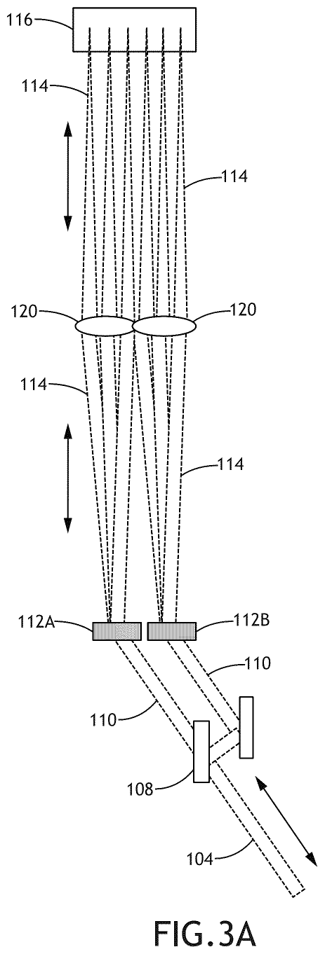

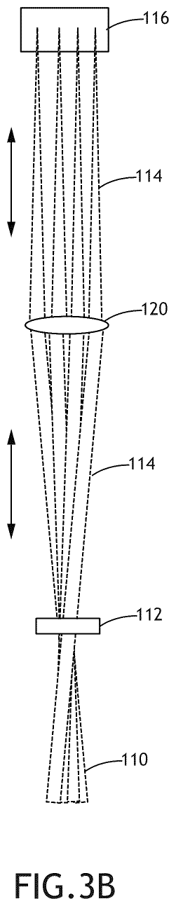

FIG. 3A illustrates a top view of a schematic of an illumination system 100 including two dispersive elements 112, in accordance with one or more embodiments of the present disclosure. FIG. 3B illustrates a side view of a schematic of an illumination system 100 including two dispersive elements 112, in accordance with one or more embodiments of the present disclosure. It is noted that the multiple dispersive elements 112 may be seen in FIG. 3A but not FIG. 3B.

In embodiments, it may be preferable to include multiple dispersive elements 112 within the spectral control subsystem 106 of the illumination system 100. For example, each of the dispersive elements 112 may be designated to form different spectra of the spectrally-dispersed beams 114.

In embodiments, the illumination system 100 includes a first dispersive element 112a and a second dispersive element 112b to form different spectra of the spectrally-dispersed beams 114. For example, the first dispersive element 112a may be designed to form portions of the spectrally-dispersed beams 114 having a wavelength above a selected threshold. In this way, the first dispersive element 112a may form portions of the spectrally-dispersed beams 114 including long wavelengths and medium wavelengths. By way of another example, the second dispersive element 112b may be designed to form portions of the spectrally-dispersed beams 114 having a wavelength below a selected threshold. In this way, the second dispersive element 112b may form portions of the spectrally-dispersed beams 114 including short wavelengths and medium wavelengths.

The beamsplitter 108 may split the illumination beams 104 into distinct beams 110 and direct different beams 110 to the first dispersive element 112a or the second dispersive element 112b.

A single two-dimensional spatial light modulator 116 may be used to modulate the spectrally-dispersed beams 114 received from both the first dispersive element 112a and the second dispersive element 112b.

Additionally, it is noted that while spectral control with two dispersive elements 112 is illustrated in FIGS. 2A and 2B, it should be noted that any number of dispersive elements 112 may be used, and therefore, the use of two dispersive elements 112 should be interpreted as illustrative rather than limiting.

While FIGS. 2A-3B illustrate embodiments including multiple two-dimensional spatial light modulators 116 and single dispersive element or multiple dispersive elements 112 and a single two-dimensional spatial light modulator 116 and numbers of dispersive elements 112 and two-dimensional spatial light modulators 116 may be used in combination with one another.

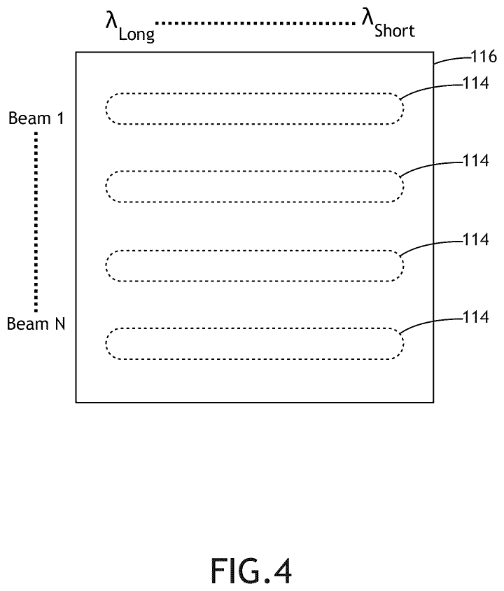

FIG. 4 illustrates multiple spectrally-dispersed beams 114 positioned on a two-dimensional spatial light modulator 116, in accordance with one or more embodiments of the present disclosure.

The two-dimensional spatial light modulators 116 also provide spatial control of intensity, phase, and/or polarization of the spectrally-dispersed beams 114. Because the spectrally-dispersed beams 114 are spectrally dispersed the control of these characteristics may be specific to the various wavelengths of the spectrally-dispersed beams 114. Additionally, the two-dimensional spatial light modulators 116 may provide for fast operation in order to make quick changes in the spatial control of the intensity, phase, and/or polarization of the spectrally-dispersed beams 114.

For example, FIG. 4 illustrates multiple beams (e.g., multiple spectrally-dispersed beams 114) arranged from Beam 1 to Beam N, where N may be any integer. Each of the spectrally-dispersed beams 114 may be spaced apart from each other on the two-dimensional spatial light modulator 116, such that the spectrally-dispersed beams 114 do not overlap.

Each of the spectrally-dispersed beams 114 may also include a range of wavelengths (e.g., long wavelengths (λ_{L}) to short wavelengths (λ_{S})). As shown in FIG. 4, each of the spectrally-dispersed beams 114 may be continuous. Such continuous spectrally-dispersed beams 114 may be indicative of a supercontinuum broad spectrum laser source.

However, each of the spectrally-dispersed beams 114 may not be continuous on the two-dimensional spatial light modulator 116. For example, in the case of distinct laser lines, each of the spectrally-dispersed beams 114 may be made up of distinct dots instead of continuous.

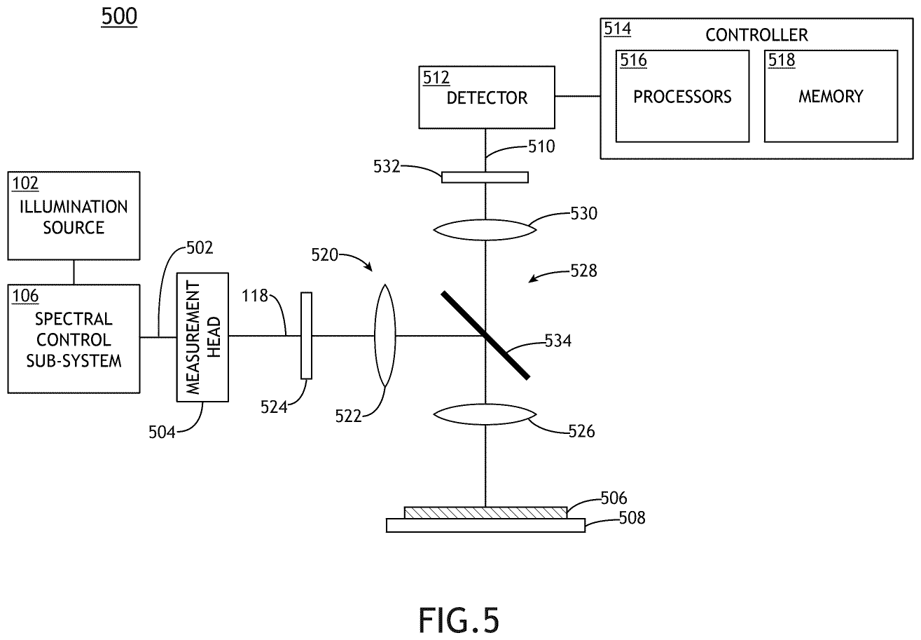

FIG. 5 illustrates a block diagram of a metrology system 500, in accordance with one or more embodiments of the present disclosure.

In embodiments, the metrology system 500 includes two or more illumination channels 502. The illumination channels 502 may be configured to couple the illumination system 100 to the measurement heads 504 of the metrology system 500. The illumination channels 502 may be any optically transmissive element. For example, illumination channels 502 may be an optical fiber.

In embodiments, the metrology system 500 includes one or more measurement heads 504. The measurement heads 504 may be configured to illuminate a portion of a sample 506 disposed on a sample stage 508 using the output beams 118 and capture sample illumination 510 from the sample 506.

In embodiments, the sample 506 may be disposed on a sample stage 508 suitable for securing the sample 506 and further configured to position the sample 506 with respect to the measurement heads 504.

The spectrally controlled output beams 118 may be fed into an optical measurement head 504 for optical metrology, inspection, or analysis. In embodiments, the measurement head 504, in accordance with the spectral control subsystem 106, is configured to illuminate different portions (e.g., semiconductor device layers) of the sample 506 with portions of illumination having different spectral attributes. For example, the measurement head 504 may be configured to illuminate a first portion of the sample 506 with illumination including a first selection of spectra and a second of the sample 506 with illumination including a second selection of spectra. The transmitted selection of illumination spectra utilized to illuminate the sample 506 or different layers of the sample 506 may be selected according to various sample, layer, and/or measurement characteristics. For example, the transmitted selection of illumination spectra may be selected and controlled according to overlay sensitivity or a predetermined or predicted level of accuracy. In embodiments, different measurement recipes may be tested over time. Therefore, the transmitted selection of illumination spectra may be based upon at least one preceding measurement.

In embodiments, the metrology system 500 includes one or more detectors 512. The detector 512 may be configured to collect sample illumination 510 scattered, reflected, or radiated by the sample 506. Based on the collected sample illumination 510, the detector may generate detection signals and/or an image of the sample 506. The detector 512 may be a spectrometer, a camera, or any other photodetector.

In embodiments, the metrology system 500 includes a controller 514. The controller 514 may be configured to direct the metrology system 500 to images based on one or more selected metrology recipes. The controller 514 may be further configured to receive data including, but not limited to, images and/or detection signals from the overlay metrology system 500. Additionally, the controller 514 may be configured to determine at least one metrology measurement associated with the sample.

In some embodiments, the controller 514 includes one or more processors 516. For example, the one or more processors 516 may be configured to execute a set of program instructions maintained in a memory 518, or memory device.

The one or more processors 516 of a controller 514 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 516 may include any device configured to execute algorithms and/or instructions (e.g., program instructions stored in memory). In embodiments, the one or more processors 516 may be embodied as a desktop computer, mainframe computer system, workstation, image computer, parallel processor, networked computer, or any other computer system configured to execute a program configured to operate or operate in conjunction with the metrology system 500, as described throughout the present disclosure. Moreover, different subsystems of the metrology system 500 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 514 may include one or more controllers housed in a common housing or within multiple housings. In this way, any controller or combination of controllers may be separately packaged as a module suitable for integration into the metrology system 500.

The memory 518 may include any storage medium known in the art suitable for storing program instructions executable by the associated one or more processors 516. For example, the memory 518 may include a non-transitory memory medium. By way of another example, the memory 518 may include, but is not limited to, a read-only memory (ROM), a random-access memory (RAM), a magnetic or optical memory device (e.g., disk), a magnetic tape, a solid-state drive, and the like. It is further noted that the memory 518 may be housed in a common controller housing with the one or more processors 516. In some embodiments, the memory 518 may be located remotely with respect to the physical location of the one or more processors 516 and the controller 514. For instance, the one or more processors 516 of the controller 514 may access a remote memory (e.g., server), accessible through a network (e.g., internet, intranet, and the like).

The detector 512 may be communicatively coupled to the controller 514. The one or more processors 516 of the controller 514 may be configured to execute one or more sets of program instructions which may cause the one or more processors 516 to generate one or more metrology measurements of the sample 506 based on the image of the sample 506 and/or the detection signals generated based on sample illumination 510, in accordance with the metrology recipe.

In embodiments, the metrology system 500 directs one or more of the output beams 118 to the sample 506 via an illumination pathway 520. The illumination pathway 520 may include one or more optical components suitable for modifying and/or conditioning the one or more output beams 118 as well as directing the one or more output beams 118 to the sample 506. In some embodiments, the illumination pathway 520 includes one or more illumination-pathway lenses 522 (e.g., to collimate the one or more output beams 118, to relay pupil and/or field planes, or the like). In embodiments, the illumination pathway 520 includes one or more illumination-pathway optics 524 to shape or otherwise control the one or more output beams 118. For example, the illumination-pathway optics 524 may include, but are not limited to, one or more polarizers, one or more phase-control optics (e.g., waveplates), one or more field stops, one or more pupil stops, one or more one or more filters (e.g., spatial and/or spectral filters), one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the metrology system 500 includes an objective lens 526 to focus the one or more output beams 118 onto the sample 506.

In embodiments, the sample 506 is disposed on a sample stage 508 suitable for securing the sample 506 and further configured to position the sample 506 with respect to the metrology system 500.

In embodiments, the metrology system 500 images the sample 506 onto at least one detector 512 by collecting at zero-order or nonzero-order diffraction through a collection pathway 528. For example, the collection pathway 528 may include optics to collect sample illumination 510 and form an image on the detector 512. The collection pathway 528 may include one or more optical elements suitable for modifying and/or conditioning the sample illumination 510 from the sample 506. In some embodiments, the collection pathway 528 includes one or more collection-pathway lenses 530 (e.g., to collimate the sample illumination 510, to relay pupil and/or field planes, or the like), which may include, but is not required to include, the objective lens 526. In some embodiments, the collection pathway 528 includes one or more collection-pathway optics 532 to shape or otherwise control the sample illumination 510. For example, the collection-pathway optics 532 may include, but are not limited to, one or more polarizers, one or more phase-control optics (e.g., waveplates), one or more field stops, one or more pupil stops, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The detector 512 may be placed at field plane conjugate to the sample 506. Further, the detector 512 may generally include any type of sensor suitable for imaging the sample 506. In some embodiments, the detector 512 is suitable for characterizing a static sample such as, but not limited to, a charge-coupled device (CCD) or a complementary metal-oxide semiconductor (CMOS) device. In this regard, the detector 512 may generate a two-dimensional image in a single measurement. In some embodiments, the detector 512 is suitable for characterizing a moving sample (e.g., a scanned sample). In this regard, the metrology system 500 may operate in a scanning mode in which the sample 506 is scanned with respect to a measurement field during a measurement. For example, the detector 512 may include a 2D pixel array with a capture time and/or a refresh rate sufficient to capture one or more images during a scan within selected image tolerances (e.g., image blur, contrast, sharpness, or the like). By way of another example, the detector 512 may include a line-scan detector to continuously generate an image one line of pixels at a time. By way of another example, the detector 512 may include a time-delay integration (TDI) detector.

The illumination pathway 520 and the collection pathway 528 of the metrology system 500 may be oriented in a wide range of configurations. For example, as illustrated in FIG. 5, the metrology system 500 may include a metrology beamsplitter 534 oriented such that a common objective lens 526 may simultaneously direct the one or more output beams 118 to the sample 506 and collect light from the sample 506. For example, the illumination pathway 520 and the collection pathway 528 may contain non-overlapping optical paths and/or separate optical components.

It is further noted that the metrology system 500 may be configured as a through the lens (TTL) metrology system 500 (e.g., as shown in FIG. 5). However, the metrology system 500 may additionally be configured as an outside the lens (OTL) metrology system 500.

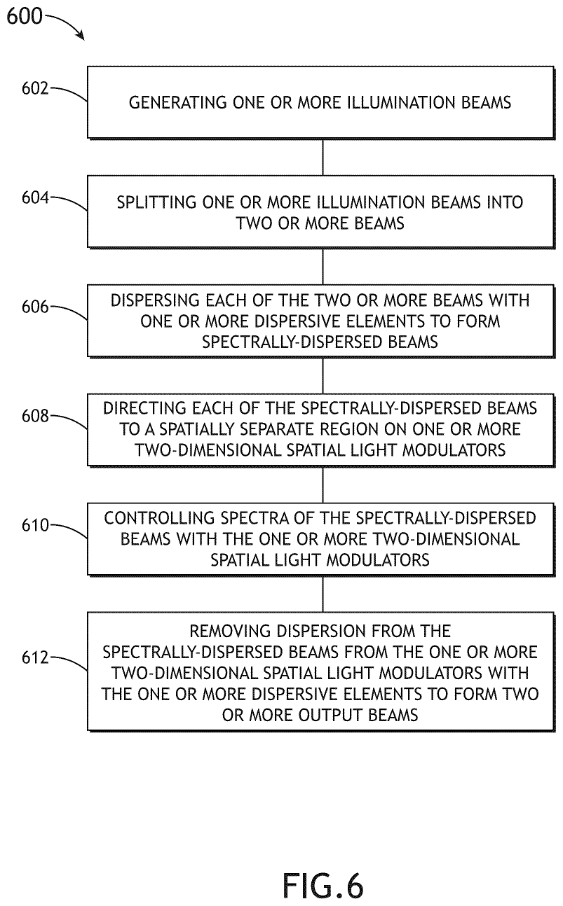

FIG. 6 illustrates a flow diagram of a metrology method 600, in accordance with one or more embodiments of the present disclosure. Applicant notes that the embodiments and enabling technologies described previously herein in the context of the illumination system 100 or the metrology system 500 should be interpreted to extend to the method 600. It is further noted, however, that the method 600 is not limited to the architecture of the illumination system 100 or the metrology system 500.

In embodiments, the method 600 includes a step 602 of generating one or more illumination beams. The illumination beams may be generated by an illumination source. The illumination source may be configured as a coherent illumination source or a noncoherent illumination source.

In embodiments, the method 600 includes a step 604 of splitting one or more illumination beams into two or more beams. The illumination beams may be directed from the illumination source to the beamsplitter. The beamsplitter may be configured to split the illumination beams into two or more beams in order to increase efficiency of an illumination system. For example, splitting illumination beams into two or more beams may allow various components of a spectral control subsystem to be shared. Sharing components of a spectral control subsystem may reduce equipment sizes and/or costs by reducing the number of spectral control subsystems required within a metrology system. Additionally, splitting the illumination beam into two or more beams may minimize costs as one light source may simultaneously illuminate multiple measurement heads.

In embodiments, the method 600 includes a step 606 of dispersing each of the two or more beams with one or more dispersive elements to form spectrally-dispersed beams. The dispersive elements may be configured to chromatically disperse each of the two or more beams in order to from the dispersed beams. The beams may be dispersed such that they are spread out between their longest wavelength and their shortest wavelength.

In embodiments, the method 600 includes a step 608 of directing each of the spectrally-dispersed beams to a spatially separate region on one or more two-dimensional spatial light modulators. The spectrally-dispersed beams may be directed to the two-dimensional spatial light modulators with optical elements. The optical elements may include one or more lenses or one or more mirrors.

In embodiments, the method 600 includes a step 610 of controlling spectra of the spectrally-dispersed beams with the one or more two-dimensional spatial light modulators. The two-dimensional spatial light modulators may be configured to alter various qualities of the light. For example, the two-dimensional spatial light modulators may be configured to control at least one of intensity, phase, or polarization of the spectrally-dispersed beams. By way of another example, the two-dimensional spatial light modulators may be configured to reduce the intensity of the spectrally-dispersed beams.

In embodiments, the method 600 includes a step 612 of removing dispersion from the spectrally-dispersed beams from the one or more two-dimensional spatial light modulators with the one or more dispersive elements to form two or more output beams. The spectrally-dispersed beams may be directed to the dispersive elements with optical elements. The optical elements may include one or more lenses or one or more mirrors. The optical elements used to direct the spectrally-dispersed beams to the dispersive elements may be the same or different than the optical elements used to direct the spectrally-dispersed beams from the dispersive elements to the two-dimensional spatial light modulators. Additionally, the dispersive elements used to remove dispersion from the spectrally-dispersed beams may be the same or different than the dispersive elements used to introduce dispersion to the spectrally-dispersed beams.

In embodiments, the method 600 includes a step of directing the two or more output beams to a measurement head. The two or more output beams may be directed to a measurement head by two or more illumination channels (e.g., a measurement channel for each of the output beams). The illumination channels may include fiber optics to transmit the output beams to the measurement heads.

In embodiments, the method 600 includes a step of illuminating a portion of a sample with the two or more output beams with the measurement head. The two or more output beams may be directed to the sample with one or more optical elements, including, but not limited to, one or more lenses or one or more beamsplitters. Additionally, each of the two or more output beams may be configured to illuminate a different portion of the sample.

In embodiments, the method 600 includes a step of collecting sample illumination from the sample with a detector. Sample illumination may be illumination that is reflected, scattered, or emitted by the sample. The detectors may be configured to receive the sample illumination and generate one or more images of the sample or one or more detection signals.

In embodiments, the method 600 includes a step of determining one or more metrology measurements of the sample based on the collected illumination. The one or more images of the sample and/or the one or more detection signals may be communicated from the detector to a controller. The controller may be configured to execute a set of program instructions in order to determine the one or more metrology measurements of the sample based on the collected illumination.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An illumination system, comprising:
one or more illumination sources, each of the one or more illumination sources configured to generate one or more illumination beams; and
a spectral control subsystem, comprising:
a beamsplitter, wherein the beamsplitter is configured to split each of the one or more illumination beams into two or more beams;
one or more dispersive elements, wherein the one or more dispersive elements are configured to spectrally disperse the two or more beams as spectrally-dispersed beams; and
one or more two-dimensional spatial light modulators, wherein each of the spectrally-dispersed beams is directed to a spatially separated region of the one or more two-dimensional spatial light modulators, wherein the two-dimensional spatial light modulator independently controls spectra of the spectrally-dispersed beams, wherein the one or more dispersive elements receive the spectrally-dispersed beams from the one or more two-dimensional spatial light modulators and remove spectral dispersion from the spectrally-dispersed beams to form two or more output beams.

2. The illumination system of claim 1, wherein the one or more illuminations sources are configured as incoherent illumination sources.

3. The illumination system of claim 1, wherein the one or more illuminations sources are configured as coherent illumination sources.

4. The illumination system of claim 1, wherein the one or more two-dimensional spatial light modulators are configured as one of a micro-mirror array, a diffractive mirror array, a silicon light valve, a liquid crystal display (LCD) array, or a liquid crystal on silicon (LCOS) array.

5. The illumination system of claim 1, wherein the one or more dispersive elements comprise:
at least one of a prism, an acousto-optic modulator, or a diffraction grating.

6. The illumination system of claim 1, wherein the one or more two-dimensional spatial light modulators control at least one of intensity, phase, or polarization of the spectrally-dispersed beams.

7. The illumination system of claim 6, wherein the one or more two-dimensional spatial light modulators are further configured to reduce the intensity of at least one of the spectrally-dispersed beams.

8. The illumination system of claim 1, wherein the one or more two-dimensional spatial light modulators comprise:
a first two-dimensional spatial light modulator to receive portions of the spectrally-dispersed beams having wavelengths above a selected threshold; and
a second two-dimensional spatial light modulator to receive portions of the spectrally-dispersed beams having wavelengths below the selected threshold.

9. The illumination system of claim 1, wherein the one or more two-dimensional spatial light modulators comprise a single two-dimensional spatial light modulator.

10. A metrology system, comprising:
one or more illumination sources, each of the one or more illumination sources configured to generate one or more illumination beams;
a spectral control subsystem, comprising:
a beamsplitter, wherein the beamsplitter is configured to split each of the one or more illumination beams into two or more beams;
one or more dispersive elements, wherein the one or more dispersive elements are configured to spectrally disperse each of the two or more beams as spectrally-dispersed beams; and
one or more two-dimensional spatial light modulators, wherein each of the spectrally-dispersed beams is directed to a spatially separated region of the one or more two-dimensional spatial light modulators, wherein the two-dimensional spatial light modulator independently controls spectra of the spectrally-dispersed beams, wherein the one or more dispersive elements receive the spectrally-dispersed beams from the one or more two-dimensional spatial light modulators and remove spectral dispersion from the spectrally-dispersed beams to form two or more output beams;
two or more illumination channels, each of the one or more illumination channels configured to receive one of the two or more output beams;
one or more measurement heads configured to illuminate a portion of a sample using the two or more output beams and capture sample illumination from the sample;
one or more detectors configured to generate detection signals based on the sample illumination from the sample; and
a controller including one or more processors configured to execute a set of program instructions stored in memory, the set of program instructions configured to cause the one or more processors to determine at least one metrology measurement of the sample based on the detection signals.

11. The metrology system of claim 10, wherein the one or more illuminations sources are configured as incoherent illumination sources.

12. The metrology system of claim 10, wherein the one or more illuminations sources are configured as coherent illumination sources.

13. The metrology system of claim 10, wherein the one or more two-dimensional spatial light modulators are configured as one of a micro-mirror array, a diffractive mirror array, a silicon light valve, a liquid crystal display (LCD) array, or a liquid crystal on silicon (LCOS) array.

14. The metrology system of claim 10, wherein the one or more dispersive elements comprise:
at least one of a prism, an acousto-optic modulator, or a diffraction grating.

15. The metrology system of claim 10, wherein the one or more two-dimensional spatial light modulators control at least one of intensity, phase, or polarization of the spectrally-dispersed beams.

16. The metrology system of claim 15, wherein the one or more two-dimensional spatial light modulators are further configured to reduce the intensity of at least one of the spectrally-dispersed beams.

17. The metrology system of claim 10, wherein the one or more two-dimensional spatial light modulators comprise:
a first two-dimensional spatial light modulator to receive portions of the spectrally-dispersed beams having wavelengths above a selected threshold; and
a second two-dimensional spatial light modulator to receive portions of the spectrally-dispersed beams having wavelengths below the selected threshold.

18. The metrology system of claim 10, wherein the one or more two-dimensional spatial light modulators comprise a single two-dimensional spatial light modulator.

19. A metrology method, comprising:
generating one or more illumination beams;
splitting one or more illumination beams into two or more beams;
dispersing each of the two or more beams with one or more dispersive elements to form spectrally-dispersed beams;
directing each of the spectrally-dispersed beams to a spatially separate region on one or more two-dimensional spatial light modulators;
controlling spectra of the spectrally-dispersed beams with the one or more two-dimensional spatial light modulators;
removing dispersion from the spectrally-dispersed beams from the one or more two-dimensional spatial light modulators with the one or more dispersive elements to form two or more output beams.

20. The metrology method of claim 19, wherein the method further comprises:
directing the two or more output beams to a measurement head.

21. The metrology method of claim 20, wherein the method further comprises:
illuminating a portion of a sample with the two or more output beams with the measurement head.

22. The metrology method of claim 21, wherein the method further comprises:
collecting sample illumination from the sample with the measurement head.

23. The metrology method of claim 22, wherein the method further comprises:
determining one or more metrology measurements of the sample based on the collected sample illumination.
